(19) United States
(12) Patent Application Publication
(10) Pub. No.: US 2025/0022759 A1
(43) Pub. Date: Jan. 16, 2025

(54) TEST STRUCTURE FOR MOL RELIABILITY EVALUATION

(71) Applicant: INTERNATIONAL BUSINESS MACHINES CORPORATION, ARMONK, NY (US)

(72) Inventors: HUIMEI ZHOU, Albany, NY (US); MIAOMIAO WANG, Albany, NY (US); Barry Paul Linder, Hastings-on-Hudson, NY (US)

(21) Appl. No.: 18/350,777

(22) Filed: Jul. 12, 2023

(51) Int. Cl. H01L 21/66; G01R 31/28; H01L 29/78

(52) U.S. Cl. CPC H01L 22/34; G01R 31/2884; H01L 22/32; H01L 29/785; H01L 2029/7858

(57) ABSTRACT

Embodiments of present invention provide a test structure. The test structure includes a scribe line area in a semiconductor substrate; a first fin and a second fin in the scribe line area and an insulating region between the first fin and the second fin; a first epitaxial region directly on top of the first fin and a second epitaxial region directly on top of the second fin; and an under-test region on top of the insulating region in the scribe line area and between the first epitaxial region and the second epitaxial region. In one aspect, the under-test region includes a gate and a first and a second sidewall spacer formed at a first and a second sidewall of the gate, the first epitaxial region being in contact with the first sidewall spacer and the second epitaxial region being in contact with the second sidewall spacer.

### BACKGROUND

The present application relates to manufacturing of semiconductor integrated circuits. More particularly, it relates to test structure for device reliability evaluation and method of making the test structure.

With the advanced scaling of semiconductor devices, integrity of structures of the semiconductor devices becomes a constant concern during the manufacturing process. To address this concern, test structures may be made during the manufacturing process and these test structures, key portions of which may be made to closely resemble those of an actual device, may be tested to confirm and/or identify weak areas of the semiconductor devices.

A semiconductor transistor includes many structural details that could potentially impact the performance of the transistor. Among the many structural details, it is identified by inventors that integrity of sidewall spacers formed at sidewalls of a gate of a transistor may ultimately determine whether the transistor will function normally or pre-maturely fail during its normal operation. Currently, there is no structure available that may be used to properly test the integrity of sidewall spacers of a transistor.

### SUMMARY

Embodiments of present invention provide a test structure. The test structure includes a scribe line area of a semiconductor substrate; an under-test region directly above the scribe line area of the semiconductor substrate; a first and a second conductive region directly adjacent to the under-test region; and a layer of dielectric material underneath the under-test region, insulating the under-test region from the semiconductor substrate.

In one embodiment, the test structure further includes a first and a second fin of silicon material longitudinally separated by the layer of dielectric material, where the first and the second conductive region are a first and a second epitaxial region formed on top of the first and the second fin of silicon material and partially in contact with the layer of dielectric material.

According to one embodiment, the under-test region includes a gate and a first and a second sidewall spacer formed at a first and a second sidewall of the gate, the first epitaxial region being in contact with the first sidewall spacer and the second epitaxial region being in contact with the second sidewall spacer.

According to another embodiment, the first and the second fin are substantially aligned to each other longitudinally and formed in a direction orthogonal to the gate.

According to yet another embodiment, a leakage current, a breakdown voltage, or a breakdown time of the first sidewall spacer is measured by applying a voltage between the first conductive region and the gate.

In one embodiment, the test structure further includes a gate oxide layer between the first sidewall spacer and the gate and between the second sidewall spacer and the gate.

In another embodiment, the test structure further includes a first and a second metal contact, the first and the second metal contact being in contact, respectively, with the first and the second conductive region.

According to one embodiment, the under-test region is a plurality of dielectric bridges between a first set of nanosheets and a second set of nanosheets.

According to another embodiment, the first conductive region is in conductive contact with the plurality of dielectric bridges of the under-test region through the first set of nanosheets, and the second conductive region is in conductive contact with the plurality of dielectric bridges of the under-test region through the second set of nanosheets.

According to yet another embodiment, the plurality of dielectric bridges includes a first dielectric material, and the first set of nanosheets are separated by the first dielectric material.

According to a further embodiment, the plurality of dielectric bridges is at least partially covered by a second dielectric material, the second dielectric material being different from the first dielectric material.

### BRIEF DESCRIPTION OF THE DRAWINGS

The present invention will be understood and appreciated more fully from the following detailed description of embodiments of present invention, taken in conjunction with accompanying drawings of which:

FIGS. 1A-1F are demonstrative illustrations of cross-sectional views of a test structure in various steps of manufacturing thereof according to one embodiment of present invention; and

FIGS. 2A-2H are demonstrative illustrations of cross-sectional views of a test structure in various steps of manufacturing thereof according to another embodiment of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

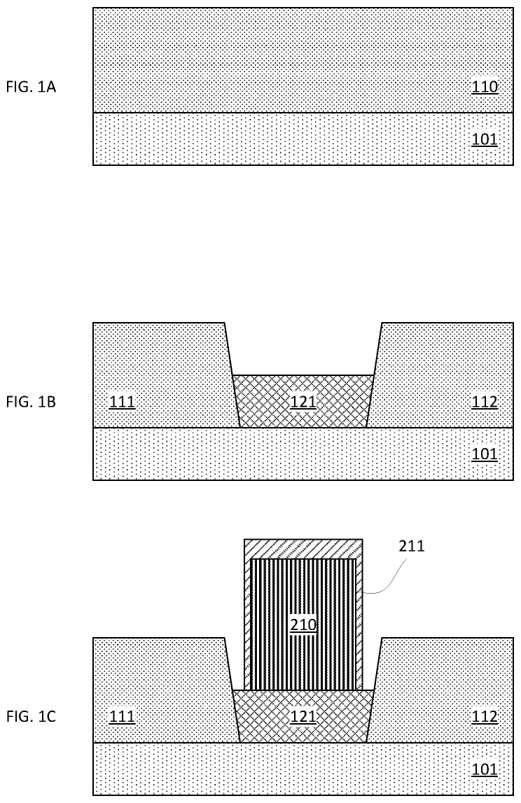

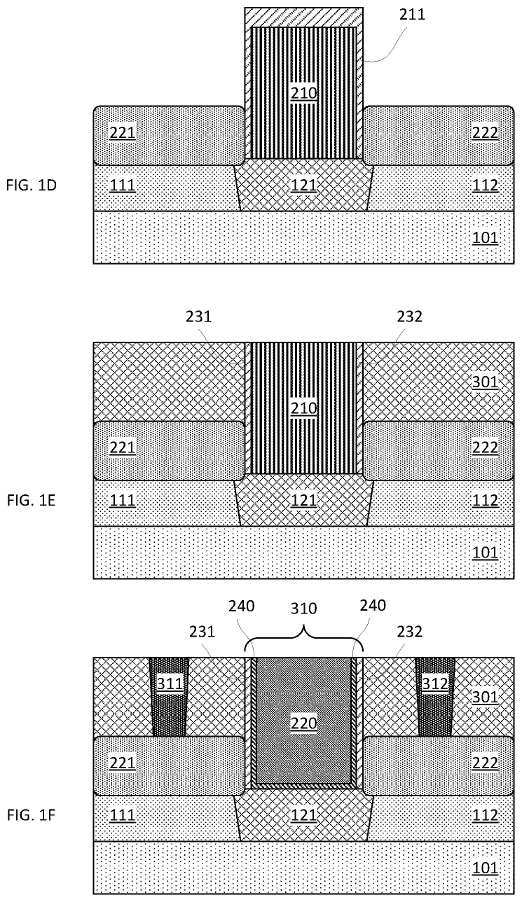

FIGS. 1A-1F are demonstrative illustrations of cross-sectional views of a test structure in various steps of manufacturing thereof according to one embodiment of present invention. More specifically, embodiments of present invention provide forming a semiconductor structure on top of a substrate such as in a scribe line area 101 of a semiconductor substrate as is illustrated in FIG. 1A. Scribe line areas may be found for example in areas outside the main device area in a chip, in a chiplet or chiplets that are modular chips that may be combined to form a larger, more complex system-on-a-chip (SoC). In one embodiment, the semiconductor structure may be a semiconductor fin, a set of silicon nanosheets, or any other structures that are generally used for forming source/drain regions of a transistor. Hereinafter, unless otherwise noted, the semiconductor structure will be described as a semiconductor fin 110 for the purpose of description of embodiments of present invention. In other words, embodiments of present invention provide forming a semiconductor fin 110 on top of a scribe line area 101 of a semiconductor substrate.

As is illustrated in FIG. 1B, embodiments of present invention provide forming a layer of dielectric material such as, for example, a shallow trench isolation (STI) 121 in the semiconductor fin 110. The STI 121 may be formed as a replacement of a channel region of a fin-type transistor therefor may be formed to divide or truncate the semiconductor fin 110 into a first fin 111 and a second fin 112. In other words, embodiments of present invention provide forming the STI 121, which may be dielectric material, such that the STI 121 is sandwiched between the first fin 111 and the second fin 112. The first fin 111 and the second fin 112 are separated longitudinally and insulated from each other by the STI 121. By the nature of their creation from a single semiconductor fin 110, the first fin 111 and the second fin 112 may be substantially aligned to each other longitudinally. In one embodiment, the STI 121 may have a height that is shorter than a height of the first and the second fin 111 and 112.

Next, as is illustrated in FIG. 1C, embodiments of present invention provide forming a conductive dummy gate structure 210 on top of the STI 121 and forming a sidewall spacer 211 surrounding sidewalls of the dummy gate structure 210. In forming the sidewall spacer 211, a conformal layer of spacer material may be formed, for example, to blanketly cover the dummy gate structure 210. The conformal layer may then be etched in a directional etching process to form the sidewall spacer 211. The dummy gate structure 210 may be formed such that the first and the second fin 111 and 112 may be in a position orthogonal to the dummy gate structure 210 as well as the sidewall spacer 211 at sidewalls of the dummy gate structure 210.

Embodiments of present invention further provide, as is illustrated in FIG. 1D, forming a first conductive region such as, for example, epitaxially growing a first epitaxial region 221 from the first fin 111 and forming a second conductive region such as, for example, epitaxially growing a second epitaxial region 222 from the second fin 112. The first epitaxial region 221 may at least partially cover the first fin 111 and the second epitaxial region 222 may at least partially cover the second fin 112. The first epitaxial region 221 and the second epitaxial region 222 may be formed next to, and in contact with, the sidewall spacer 211 at the sidewalls of the dummy gate structure 210. Moreover, the first epitaxial region 221 and the second epitaxial region 222 may be at least partially in contact with the STI 121.

Embodiments of present invention further provide, as is illustrated in FIG. 1E, depositing a dielectric layer 301 blanketly covering the first and the second epitaxial region 221 and 222, the sidewall spacer 211, and the dummy gate structure 210. Next, a chemical-mechanical-polishing (CMP) process may be applied to planarize the top surface of the dielectric layer 301. The top surface of the dummy gate structure 210 may be exposed by the CMP process after removing a top portion of the sidewall spacer 211 and possibly a gate cap layer on top of the dummy gate structure 210. The removal of the top portion of the sidewall spacer 211 creates a first sidewall spacer 231 and a second sidewall spacer 232.

Next, as is illustrated in FIG. 1F, the dummy gate structure 210 may be replaced with a metal gate 220, for example, in a replacement-metal-gate (RMG) process thereby forming an under-test region 310. The under-test region 310 is directly above the scribe line area 101 of the semiconductor substrate. In one embodiment, depending on the type of testing that is needed and/or planned, a high-k gate oxide layer 240 may be deposited next to the first and the second sidewall spacer 231 and 232 after the dummy gate structure 210 is removed and before the metal gate 220 is formed. The metal gate 220 may be formed by depositing a gate metal on top of the gate oxide layer 240 to form the under-test region 310. As is formed, the first and the second fin 111 and 112 may be orthogonal to the metal gate 220. Moreover, one or more conductive contacts such as a first and a second metal contact 311 and 312 may be formed in the dielectric layer 301. The first and the second metal contact 311 and 312 are in contact with the first and the second conductive regions such as the first and the second epitaxial region 221 and 222.

The under-test region 310 may include the first and the second sidewall spacer 231 and 232 that are the subject of testing for the integrity thereof. For example, the first sidewall spacer 231 may be tested for its leakage current, breakdown voltage, and/or breakdown time, among other properties, that may affect the performance of a transistor that uses such sidewall spacer. During testing, for example, a voltage may be applied to the first sidewall spacer 231 at the metal gate 220 and at the first epitaxial region 221 via the first metal contact 311, and the leakage current, breakdown voltage, and/or breakdown time may be measured or recorded.

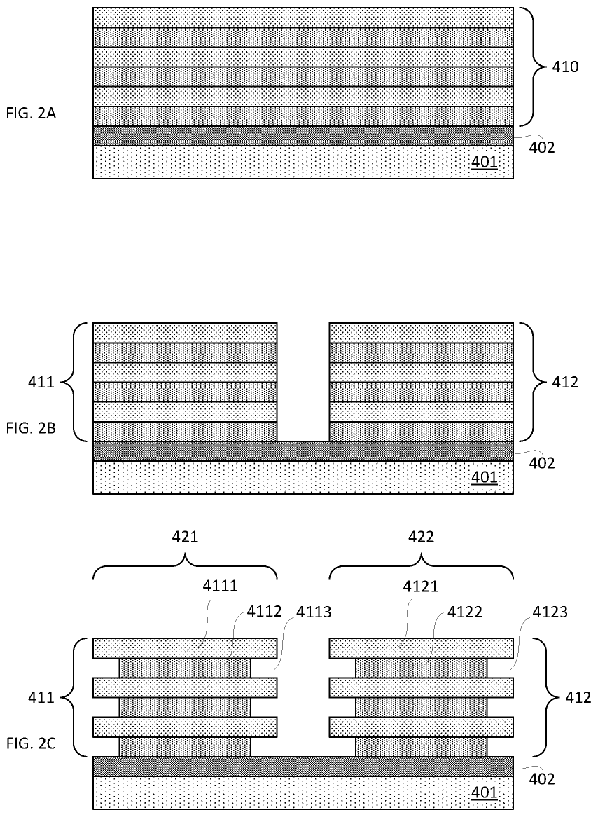

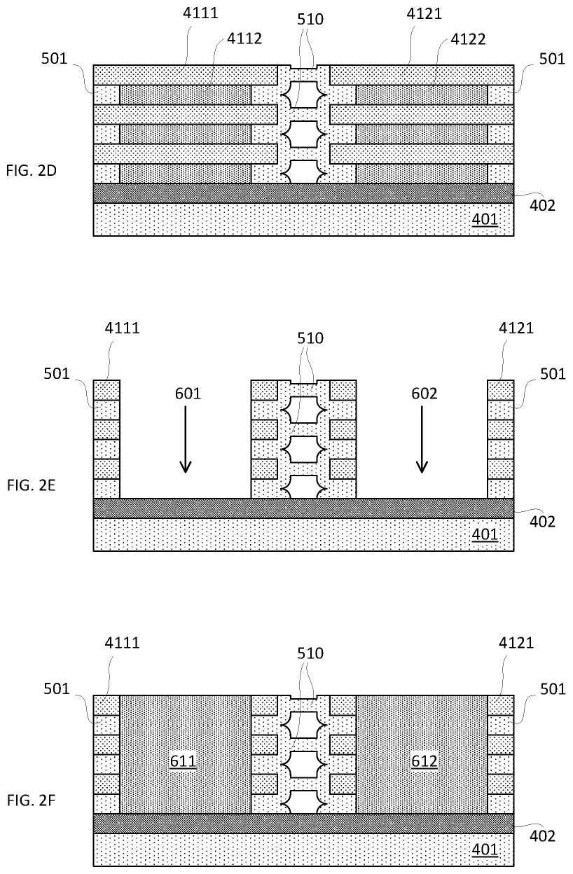

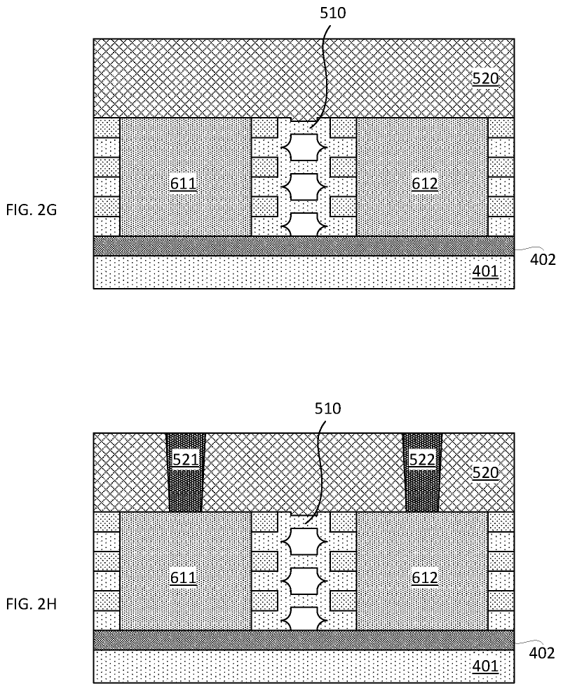

FIGS. 2A-2H are demonstrative illustrations of cross-sectional views of a test structure in various steps of manufacturing thereof according to another embodiment of present invention. More specifically, embodiments of present invention provide forming a semiconductor structure 410 on top of a scribe line area of a semiconductor substrate 401 as is illustrated in FIG. 2A. In one embodiment, the semiconductor structure 410 may be a stack of nanosheets that are separated by a stack of sacrificial sheets. A layer 402 of dielectric material may be formed on top of the scribe line area of the semiconductor substrate 401, and the stack of nanosheets may be insulated from the semiconductor substrate 401 by the layer 402 of dielectric material.

Embodiments of present invention provide etching or recessing the stack of nanosheets of the semiconductor structure 410 into a first set of nanosheets 411 and a second set of nanosheets 412, as is illustrated in FIG. 2B, in a step of forming a first nanosheet transistor 421 and a second nanosheet transistor 422. For example, the first nanosheet transistor 421 may include a first set of nanosheets 4111 that are separated by a first set of sacrificial sheets 4112. The second nanosheet transistor 422 may include a second set of nanosheets 4121 that are separated by a second set of sacrificial sheets 4122. Embodiments of present invention further provide performing indentation of the first and the second set of sacrificial sheets 4112 and 4122 to create a first set of indents 4113 and a second set of indents 4123, as is illustrated in FIG. 2C. The indentation may be performed through a selective etching process that applies the etch selectivity between the nanosheets 4111 (and 4121) and the sacrificial sheets 4112 (and 4122) that are generally materials containing different amount of germanium (Ge).

As is illustrated in FIG. 2D, embodiments of present invention provide depositing a dielectric material in the first and second sets of indents 4113 and 4123 to form inner spacers 501. In addition to being deposited at the ends of the first and the second sacrificial sheets 4112 and 4122 in forming the inner spacers 501, the same dielectric material may also be deposited at the ends of the first and the second set of nanosheets 4111 and 4121 thereby forming a plurality of dielectric bridges 510, which connect the first set of nanosheets 4111 with the second set of nanosheets 4121. The plurality of dielectric bridges 510, made of dielectric material, may be tested for its integrity, such as leakage current, breakdown voltage, and/or breakdown time, during a follow-up testing procedure. In other words, embodiments of present invention provide forming an under-test region of a test structure that includes the plurality of dielectric bridges 510.

As is illustrated in FIG. 2E, embodiments of present invention provide forming conductive regions that may be used in testing the plurality of dielectric bridges 510. More particularly, embodiments of present invention provide removing portions of the first and the second set of nanosheets 411 and 412, including removing the first and the second set of sacrificial sheets, for example in a directional or anisotropic etching process coupled with a lithographic patterning process to form a mask, to form a first opening 601 and a second opening 602. In other words, the first and the second opening 601 and 602 may be created in areas where metal gates of the first and the second nanosheet transistor 421 and 422 would have normally been formed.

Embodiments of present invention further provide, as is illustrated in FIG. 2F, filling the first and the second opening 601 and 602 with conductive material to form a first conductive region 611 and a second conductive region 612. The first and the second conductive region 611 and 612 may be used in the reliability testing of the plurality of dielectric bridges 510 in applying testing voltages to the plurality of dielectric bridges 510. More specifically, testing voltages may be applied to the plurality of dielectric bridges 510 through the first and the second conductive region 611 and 612 and via the remaining portions of the first and the second set of nanosheets 4111 and 4121 adjacent to the plurality of dielectric bridges 510.

Embodiments of present invention further provide forming a dielectric layer 520 on top of the plurality of dielectric bridges 510 of under-test region and above the first and the second conductive region 611 and 612, as is illustrated in FIG. 2G. The dielectric layer 520 may include a dielectric material that is different from the dielectric material that forms the dielectric bridges 510, and from the dielectric material that separates the first set of nanosheets 4111 and the second set of nanosheets 4121 in forming the inner spacers 501. Embodiments of present invention further provide forming a first metal contact 521 and a second metal contact 522 in the dielectric layer 520 as is illustrated in FIG. 2H. The first metal contact 521 may contact the first conductive region 611 and the second metal contact 522 may contact the second conductive region 612.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A test structure comprising:
a scribe line area of a semiconductor substrate;
an under-test region directly above the scribe line area of the semiconductor substrate;
a first and a second conductive region directly adjacent to the under-test region; and
a layer of dielectric material underneath the under-test region, insulating the under-test region from the semiconductor substrate.

2. The test structure of claim 1, further comprising a first and a second fin of silicon material longitudinally separated by the layer of dielectric material, wherein the first and the second conductive region are a first and a second epitaxial region formed on top of the first and the second fin of silicon material and partially in contact with the layer of dielectric material.

3. The test structure of claim 2, wherein the under-test region includes a gate and a first and a second sidewall spacer formed at a first and a second sidewall of the gate, the first epitaxial region being in contact with the first sidewall spacer and the second epitaxial region being in contact with the second sidewall spacer.

4. The test structure of claim 3, wherein the first and the second fin are substantially aligned to each other longitudinally and formed in a direction orthogonal to the gate.

5. The test structure of claim 4, wherein a leakage current, a breakdown voltage, or a breakdown time of the first sidewall spacer is measured by applying a voltage between the first conductive region and the gate.

6. The test structure of claim 3, further comprising a gate oxide layer between the first sidewall spacer and the gate and between the second sidewall spacer and the gate.

7. The test structure of claim 1, further comprising a first and a second metal contact, the first and the second metal contact being in contact, respectively, with the first and the second conductive region.

8. The test structure of claim 1, wherein the under-test region is a plurality of dielectric bridges between a first set of nanosheets and a second set of nanosheets.

9. The test structure of claim 8, wherein the first conductive region is in conductive contact with the plurality of dielectric bridges of the under-test region through the first set of nanosheets, and the second conductive region is in conductive contact with the plurality of dielectric bridges of the under-test region through the second set of nanosheets.

10. The test structure of claim 9, wherein the plurality of dielectric bridges includes a first dielectric material, and the first set of nanosheets are separated by the first dielectric material.

11. The test structure of claim 10, wherein the plurality of dielectric bridges is at least partially covered by a second dielectric material, the second dielectric material being different from the first dielectric material.

12. A test structure comprising:
a scribe line area of a semiconductor substrate;
a first fin and a second fin in the scribe line area, and an insulating region between the first fin and the second fin;
a first epitaxial region directly on top of the first fin and a second epitaxial region directly on top of the second fin; and
an under-test region on top of the insulating region in the scribe line area and between the first epitaxial region and the second epitaxial region.

13. The test structure of claim 12, wherein the under-test region includes a gate and a first and a second sidewall spacer formed at a first and a second sidewall of the gate, the first epitaxial region being in contact with the first sidewall spacer and the second epitaxial region being in contact with the second sidewall spacer.

14. The test structure of claim 13, wherein the first fin and the second fin are substantially aligned to each other and are formed in a direction orthogonal to the gate.

15. The test structure of claim 14, further comprising a gate oxide layer between the first sidewall spacer and the gate and between the second sidewall spacer and the gate.

16. The test structure of claim 12, further comprising a first and a second metal contact, the first and the second metal contact being in contact with the first and the second epitaxial region respectively.

17. A test structure comprising:
a scribe line area of a semiconductor substrate;
an under-test region above the scribe line area, the under-test region including a plurality of dielectric bridges between a first set of nanosheets and a second set of nanosheets;
a first conductive region, the first set of nanosheets being between the first conductive region and the under-test region; and
a second conductive region, the second set of nanosheets being between the second conductive region and the under-test region.

18. The test structure of claim 17, wherein the first conductive region is in conductive contact with the plurality of dielectric bridges of the under-test region through the first set of nanosheets, and the second conductive region is in conductive contact with the plurality of dielectric bridges of the under-test region through the second set of nanosheets.

19. The test structure of claim 18, wherein the plurality of dielectric bridges is made of a first dielectric material, and the first and the second set of nanosheets are separated by the first dielectric material.

20. The test structure of claim 19, wherein the plurality of dielectric bridges is covered by a second dielectric material at a top thereof, the second dielectric material being different from the first dielectric material.
